(19) United States
(12) Patent Application Publication
(10) Pub. No.: US 2008/0239105 A1
(43) Pub. Date: Oct. 2, 2008

(54) SAMPLE AND HOLD CIRCUITS FOR CMOS IMAGERS

(76) Inventor: Weize Xu, Rochester, NY (US)

Correspondence Address: Frank Pincelli, Patent Legal Staff;Eastman Kodak Company, 343 State Street, Rochester, NY, 14650-2201, US

(21) Appl. No.: 11/694,291

(22) Filed: Mar. 30, 2007

(51) Int. Cl. H01L 27/00; H04N 5/217; H04N 5/335

(52) U.S. Cl. 348/241; 348/302; 250/208.1

(57) ABSTRACT

A CMOS image sensor includes a photodiode for receiving incident light that is converted to a charge signal; a transfer mechanism for transferring the charge to a sensing node that converts the charge signal to an image voltage signal; and a sample-and-hold circuit. The sample-and-hold circuit includes a capacitor that receives the image voltage signal; and only one buffer amplifier that passes the image voltage signal to a differential amplifier. The buffer amplifier also receives a reset signal that is passed to the differential amplifier.

### FIELD OF THE INVENTION

The invention relates generally to the field of CMOS image sensors. More specifically, the invention relates to reducing spatial requirements of the CMOS image sensor by eliminating some components, such as a second operational amplifier, as in prior art CMOS image sensors.

### BACKGROUND OF THE INVENTION

A MOS imager includes solid-state image sensing devices formed from either NMOS, PMOS or CMOS. Also, these MOS imagers can be either active pixel sensors (APS) having amplification provided on a per pixel basis or passive pixel sensors (PPS) where photogenerated charge from a selected photodetector is simply enabled onto a column bus. These MOS imagers are typically formed in a matrix of rows and columns with select circuitry allocated to individual rows and columns. The imaging arrays will typically select a row of the pixel array and transfer to a sample and hold array. Then, the sample-and-hold array reads out each column one at a time; therefore, circuitry allocated for each of the columns of the sample and hold array has proved a useful feature within prior art devices. A problem that exists within these prior art devices is that of fixed pattern noise (FPN) that can occur due to process variations and capacitive coupling in the sample-and-hold circuitry that is provided for each of the columns.

MOS imagers frequently have correlated double sampling (CDS) circuits that are provided for each of the columns for reducing FPN. These CDS circuits will sample and hold each reset value for each of the photodetectors as well as an image signal value for each of the photodetectors in order to eliminate offsets that can inherently occur within the photodetectors due to the location of the photodetector [as compared to the column circuitry] or simply due to process variations from photodetector to photodetector. The output from the CDS circuits is then provided to an amplifier or an analog-to-digital converter (ADC) for output.

However, these prior art devices still exhibit undesirable FPN. Currently, the most prolific type of MOS imager is APS devices based on CMOS technology. Because CMOS is so widely used for semiconductor circuit applications, it offers the opportunity to create imager designs with numerous circuits placed on the same chip as the sensor. However, imagers have not conventionally been done in CMOS until recently. These recent CMOS imager designs have been very competitive in the low end of the imager market, but have yet to achieve prominence in the high end of the market. This is most notably because of noise factors and fill factors. The fill factor problem results from placing circuit in the pixel area itself where the photodetector is situated, taking up space that could otherwise be used by the photodetector. Noise problems exist in the column circuit typically employed by CMOS APS devices resulting in fixed pattern noise (FPN). Conventional approaches to reduce the FPN noise problem lead those skilled in the art towards solutions such as the placement of unity gain amplifiers (UGA) within individual pixels. This conventional approach has two sample-and-hold capacitors and two associated amplifier circuits in each column of the sample-and-hold array.

Consequently, a need exists for a sample and hold circuit with reduced spatial requirements that still addresses the FPN noise drawbacks.

### SUMMARY OF THE INVENTION

The present invention is directed to overcoming one or more of the problems set forth above. Briefly summarized, according to one aspect of the present invention, the invention resides in a CMOS image sensor comprising (a) a photodiode for receiving incident light that is converted to a charge signal; (b) a transfer mechanism for transferring the charge to a sensing node that converts the charge signal to an image voltage signal; and (c) a sample-and-hold circuit comprising: (i) a capacitor that receives the image voltage signal; and (ii) only one buffer amplifier that passes the image voltage signal to a differential amplifier; wherein the buffer amplifier also receives a reset signal that is passed to the differential amplifier.

These and other aspects, objects, features and advantages of the present invention will be more clearly understood and appreciated from a review of the following detailed description of the preferred embodiments and appended claims, and by reference to the accompanying drawings.

### ADVANTAGEOUS EFFECT OF THE INVENTION

The present invention has the advantage of reducing spatial requirements by having less circuitry in the sample-and-hold circuits.

### BRIEF DESCRIPTION OF THE DRAWINGS

FIG. 1 is a schematic diagram of an image sensor of the present invention;

FIG. 2 is a schematic diagram of a typical pixel and sample-and-hold circuit of FIG. 1;

FIG. 3 is a timing diagram for the circuit of FIG. 2; and

FIG. 4 is a digital camera of the present invention having the image sensor of FIG. 1.

### DETAILED DESCRIPTION OF THE INVENTION

Before discussing the present invention in detail, it is instructive to note that the present invention is preferably used in, but not limited to, a CMOS active pixel sensor. Active pixel sensor refers to an active electrical element within the pixel, other than transistors functioning as switches. For example, the floating diffusion or amplifier are active elements. CMOS refers to complementary metal oxide silicon type electrical components such as transistors which are associated with the pixel, but typically not in the pixel, and which are formed when the source/drain of a transistor is of one dopant type (for example p-type) and its mated transistor is of the opposite dopant type (for example n-type).

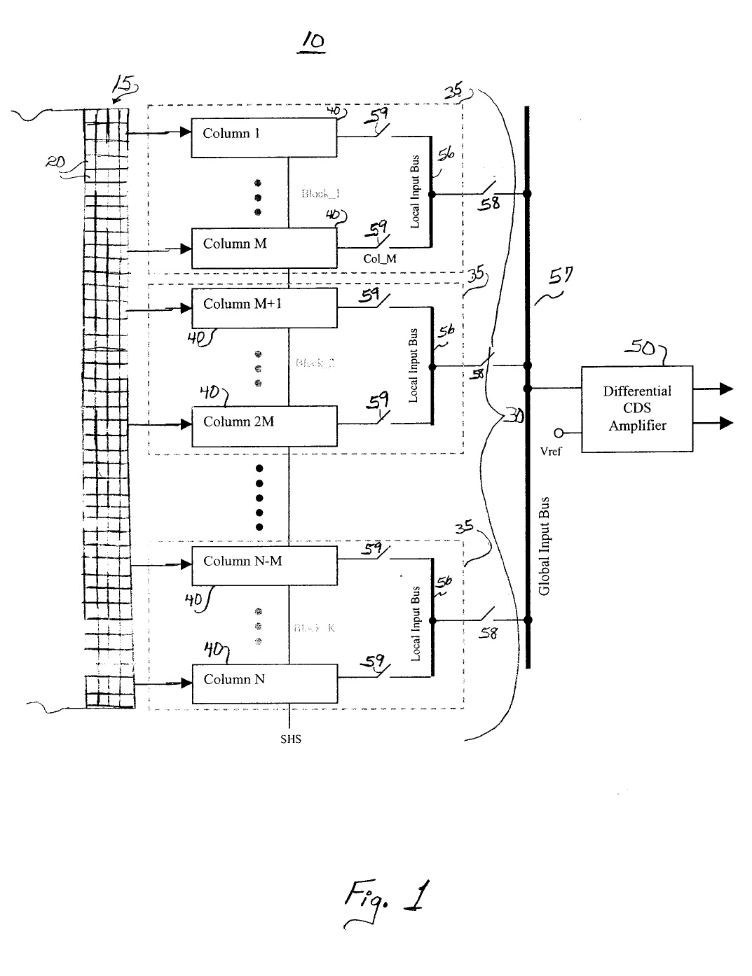

CMOS devices include some advantages one of which is it consumes less power. Referring to FIG. 1, there is shown a CMOS active image sensor 10 having a pixel array 15 with a plurality of pixels 20. It is noted for clarity that CMOS support circuitry (not shown) is electrically connected to the pixel array 15 for providing necessary operational signals to the pixel array 15 as is well known in the art. A sample-and-hold array 30 having a plurality of sub-arrays 35, and each sub-array 35 includes a plurality of column sample-and-hold circuits 40 which are connected to the pixel array 15 for receiving and processing the signals from the pixel array 15. A global differential CDS amplifier 50 is connected to the output of the sample-and-hold array 30 via a local bus 56 and global bus 57 for further processing the signals as will be described in detail hereinbelow. A plurality of switches 58 selectively and respectively connect the local bus 56 to the global bus 57, a plurality of switches 59 selectively and respectively connect the local bus 56 to the global bus 57.

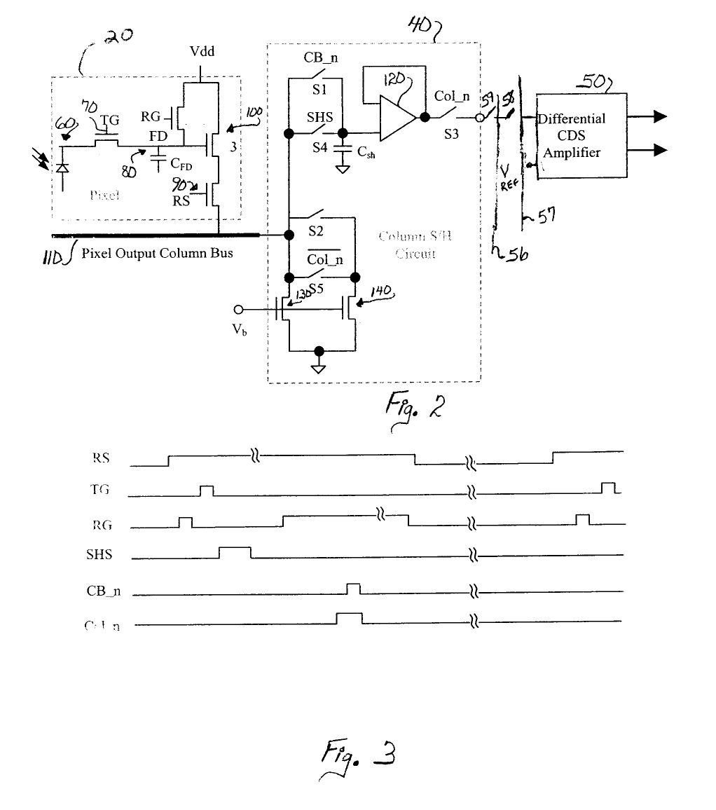

Referring to FIG. 2, there is shown a pixel 20 and its associated sample-and-hold circuit 40. Only one pixel 20 and sample-and-hold circuit 40 are shown for clarity, although there are a plurality of both pixels 20 and sample-and-hold circuits 40 as described hereinabove. The CMOS image sensor 10 includes a photodiode (or alternatively a pinned photodiode) 60 for receiving incident light (indicated by the arrows) that is converted to a charge signal which is representative of an image. A transfer gate 70 transfers the charge to a sensing node 80, preferably a floating diffusion. When a row select gate of the row select transistor 90 is pulsed, the charge is then passed from the sensing node 80 as a voltage signal to an amplifier 100, preferably a source follower. The row select transistor 90 selects the row of pixels to pass the signal from the amplifier 100 to the pixel output column bus 110.

To permit the voltage to pass to the operational amplifier 120, switches S2 and S4 are closed while switch S1 remains open to charge the sample and hold capacitor Cₛₕ. It is noted that capacitor Cₛₕ holds the image signal. Then switches S1, S2, S4 and S5 are opened, and the column select switch S3 is closed for passing the image signal to the differential amplifier 50 via the local bus 56 and global bus 57 while switches 58 and 59 are closed. V_{ref} is a predetermined reference voltage as is readily understood by those skilled in the art.

The reset gate of the reset transistor 90 is then pulsed for resetting the floating diffusion 80 to a known voltage or signal level. With the row select gate still pulsed, switch S1 is closed and switch S4 is opened, and the reset signal is passed to the operational amplifier 120 through switch S1, preferably a unity gain amplifier. The reset signal is passed from the operational amplifier 120 to a differential CDS amplifier 50 where the difference of the two signal produce an image signal with any noise (residual charge) substantially removed therefrom by subtracting out the residual signal.

The transistors 130 and 140 and switches S2 and S5 function in operational combination to provide a circuit for providing a path for biasing current produced by voltage V_{b}. It is noted that this circuit provides a power up or power down current for the pixel amplifier 100. When both switches S2 and S5 are opened, the amplifier 100 is a power down mode, and when both switches S2 and S5 are closed, the amplifier 100 is in a power up mode.

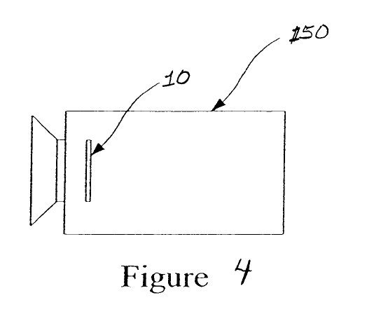

Referring to FIG. 3, there is shown a timing diagram for the circuits of FIG. 2 where RS is the reset transistor, TG is the transfer gate, RG is the reset transistor, SHS is the sample and hold circuit, CB n is signal for switch S1, and Col n is signal for switch S3.

Referring to FIG. 4, there is shown a digital camera 150 containing the above described image sensor 10.

The invention has been described with reference to a preferred embodiment. However, it will be appreciated that variations and modifications can be effected by a person of ordinary skill in the art without departing from the scope of the invention.

### PARTS LIST

10 image sensor
15 pixel array
20 plurality of pixels
30 sample-and-hold array
35 sub-array
40 column sample-and-hold circuits
50 Differential CDS Amplifier
56 local bus
57 global bus
58 switches
59 switches
60 photodiode/pinned photodiode
70 transfer gate
80 sensing node/floating diffusion
90 row select transistor
100 amplifier/source follower
110 output column bus
120 operational amplifier
130 biasing transistor
140 biasing transistor
150 digital camera

1. An active image sensor comprising:
(a) a photodiode for receiving incident light that is converted to a charge signal;
(b) a transfer mechanism for transferring the charge to a sensing node that converts the charge signal to an image voltage signal; and
(c) a sample and hold circuit comprising:
(i) only one capacitor that receives the image voltage signal; and
(ii) only one buffer amplifier that passes the image voltage signal to a differential amplifier;
wherein the buffer amplifier also receives a reset signal that is passed to the differential amplifier.

2. The active image sensor as in claim 1, wherein the buffer amplifier is a unity gain amplifier.

3. The active image sensor as in claim 1 further comprising two operational switches connected to the capacitor for respectively transferring the image voltage signal and the reset signal.

4. The active image sensor as in claim 1, wherein the image sensor is CMOS.

5. A digital camera comprising:
a CMOS image sensor comprising:
(a) a photodiode for receiving incident light that is converted to a charge signal;
(b) a transfer mechanism for transferring the charge to a sensing node that converts the charge signal to an image voltage signal; and
(c) a sample and hold circuit comprising:
(i) only one capacitor that receives the image voltage signal; and
(ii) only one buffer amplifier that passes the image voltage signal to a differential amplifier;
wherein the buffer amplifier also receives a reset signal that is passed to the differential amplifier.

6. The digital camera as in claim 5, wherein the buffer amplifier is a unity gain amplifier.

7. The digital camera as in claim 5 further comprising two operational switches connected to the capacitor for respectively transferring the image voltage signal and the reset signal.

8. The digital camera as in claim 5, wherein the image sensor is CMOS.
